(19) United States
(12) Patent Application Publication
(10) Pub. No.: US 2025/0040300 A1
(43) Pub. Date: Jan. 30, 2025

(54) DISPLAY PANEL AND DISPLAY DEVICE

(71) Applicant: Wuhan Tianma Micro-Electronics Co., Ltd., Wuhan (CN)

(72) Inventors: Fengyun WU, Wuhan (CN); Yangzhao MA, Wuhan (CN)

(21) Appl. No.: 18/600,139

(22) Filed: Mar. 8, 2024

(30) Foreign Application Priority Data
Jul. 26, 2023 (CN) 202310936556.0

(51) Int. Cl. H01L 33/24; H01L 27/12; H01L 33/38

(52) U.S. Cl. CPC H01L 33/24; H01L 27/1222; H01L 27/124; H01L 33/38

(57) ABSTRACT

A display panel and a display device are provided. The display panel includes a display area, including a first display area and repeating units that including a first light-emitting element column, a second light-emitting element column, a third light-emitting element column and a fourth light-emitting element column. The second light-emitting element column and the fourth light-emitting element column each includes a third color light-emitting element, and third color light-emitting elements in the second light-emitting column and the fourth light-emitting element column are arranged in a staggered manner in the first direction. In a direction perpendicular to a plane of the display panel, a light-emitting element includes an anode, a light-emitting material layer and a cathode stacked in sequence; and in the first display area, in the direction perpendicular to the plane, in the third color light-emitting element, a shape of the anode includes an arc-shaped edge.

### CROSS-REFERENCE TO RELATED APPLICATION

This application claims the priority of Chinese Patent Application No. 202310936556.0, filed on Jul. 26, 2023, the content of which is incorporated by reference in its entirety.

### TECHNICAL FIELD

The present disclosure generally relates to the field of display technologies and, more particularly, relates to a display panel and a display device.

### BACKGROUND

With the development of display technologies, display panels with high screen-to-body ratios have become one of the most researched topics. To increase the screen-to-body ratio, an optical component reserve area is usually set up in the display area of the display panel to accommodate optical components, such as camera modules, infrared sensing devices, and fingerprint recognition components.

Currently, when optical elements are accommodated in the reserved area for optical elements, external light needs to pass through the display panel to reach the optical elements. The display panel is covered with regular wirings and periodically arranged unit pixels. When light passes through the display panel, it will form a diffraction phenomenon, thus affecting the optical performance of the optical elements. The present disclosed display panel and display devices are direct to solve one or more problems set forth above and other problems in the arts.

### SUMMARY

One aspect of the present disclosure provides a display panel. The display panel includes a display area. The display area includes a first display area and a plurality of repeating units. A repeating unit of the plurality of repeating units includes a plurality of light-emitting elements; the plurality of light-emitting elements include a first color light-emitting element, a second color light-emitting element and a third color light-emitting element; the plurality of repeating units include a first light-emitting element column, a second light-emitting element column, a third light-emitting element column and a fourth light-emitting element column sequentially arranged in a first direction; the first light-emitting element column and the third light-emitting element column each includes a first color light-emitting element and a second color light-emitting element arranged in a second direction, and an arrangement manner of the light-emitting elements in the first light-emitting element column is same as an arrangement manner of the light-emitting elements in the third light-emitting element column, and the first direction intersects with the second direction. The second light-emitting element column and the fourth light-emitting element column each include a third color light-emitting element, and third color light-emitting elements in the second light-emitting column and third color light-emitting elements in the fourth light-emitting element column are arranged in a staggered manner in the first direction. In a direction perpendicular to a plane of the display panel, a light-emitting element includes an anode, a light-emitting material layer and a cathode that are stacked in sequence; and in the first display area, in the direction perpendicular to the plane of the display panel, in the third color light-emitting element, a shape of the anode includes an arc-shaped edge.

Another aspect of the present disclosure provides a display device. The display device includes a display panel. The display panel includes a display area. The display area includes a first display area and a plurality of repeating units. A repeating unit of the plurality of repeating units includes a plurality of light-emitting elements; the plurality of light-emitting elements include a first color light-emitting element, a second color light-emitting element and a third color light-emitting element; the plurality of repeating units include a first light-emitting element column, a second light-emitting element column, a third light-emitting element column and a fourth light-emitting element column sequentially arranged in a first direction; the first light-emitting element column and the third light-emitting element column each includes a first color light-emitting element and a second color light-emitting element arranged in a second direction, and an arrangement manner of the light-emitting elements in the first light-emitting element column is same as an arrangement manner of the light-emitting elements in the third light-emitting element column, and the first direction intersects with the second direction. The second light-emitting element column and the fourth light-emitting element column each include a third color light-emitting element, and third color light-emitting elements in the second light-emitting column and third color light-emitting elements in the fourth light-emitting element column are arranged in a staggered manner in the first direction. In a direction perpendicular to a plane of the display panel, a light-emitting element includes an anode, a light-emitting material layer and a cathode that are stacked in sequence; and in the first display area, in the direction perpendicular to the plane of the display panel, in the third color light-emitting element, a shape of the anode includes an arc-shaped edge.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates a top view of an exemplary display panel according to various disclosed embodiments of the present disclosure;

FIG. 2 illustrates a zoomed-in view of the section A of the display panel in FIG. 1;

FIG. 3 illustrates a top view of a type of repeating units in the first display area of an exemplary display panel according to various disclosed embodiments of the present disclosure;

FIG. 4 illustrates a B-B′-sectional view of the display panel in FIG. 3;

FIG. 5 illustrates another zoomed-in view of the section A of the display panel in FIG. 1;

FIG. 6 illustrates a top view of another type of repeating units in the first display area of an exemplary display panel according to various disclosed embodiments of the present disclosure;

FIG. 7 illustrates a C-C′-sectional view of the display panel in FIG. 6;

FIG. 8 illustrates another zoomed-in view of the section A of the display panel in FIG. 1;

FIG. 9 illustrates a top view of another type of repeating units in the first display area of an exemplary display panel according to various disclosed embodiments of the present disclosure;

FIG. 10 illustrates a top view of another type of repeating units in the first display area of an exemplary display panel according to various disclosed embodiments of the present disclosure;

FIG. 11 illustrates a top view of another type of repeating units in the first display area of an exemplary display panel according to various disclosed embodiments of the present disclosure;

FIG. 12 illustrates a D-D′-sectional view of the display panel in FIG. 11;

FIG. 13 illustrates a top view of another type of repeating units in the first display area of an exemplary display panel according to various disclosed embodiments of the present disclosure;

FIG. 14 illustrates an E-E′-sectional view of the display panel in FIG. 13;

FIG. 15 illustrates another E-E′-sectional view of the display panel in FIG. 13;

FIG. 16 illustrates a top view of another type of repeating units in the first display area of an exemplary display panel according to various disclosed embodiments of the present disclosure;

FIG. 17 illustrates an F-F′-sectional view of the display panel in FIG. 16; and

FIG. 18 illustrates an exemplary display device according to various disclosed embodiments of the present disclosure.

### DETAILED DESCRIPTION

Various exemplary embodiments of the present disclosure will now be described in detail with reference to the accompanying drawings. It should be noted that the relative arrangements of components and steps, numerical expressions and numerical values set forth in these embodiments do not limit the scope of the present disclosure unless specifically stated otherwise.

The following description of at least one exemplary embodiment is merely illustrative in nature and in no way taken as limiting the disclosure, its application or uses.

Techniques, methods and devices known to those of ordinary skill in the relevant art may not be discussed in detail, but where appropriate, such techniques, methods and devices should be considered parts of the description.

In all examples shown and discussed herein, any specific values should be construed as exemplary only, and not as limitations. Therefore, other instances of the exemplary embodiment may have different values.

It should be noted that like numerals and letters denote like items in the following figures. Therefore, once an item is defined in one figure, it does not require further discussion in subsequent figures.

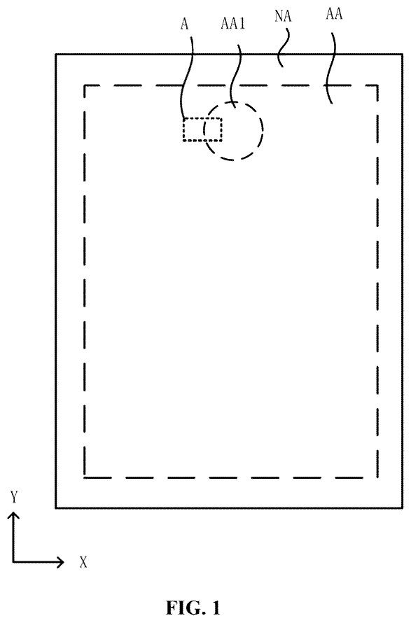

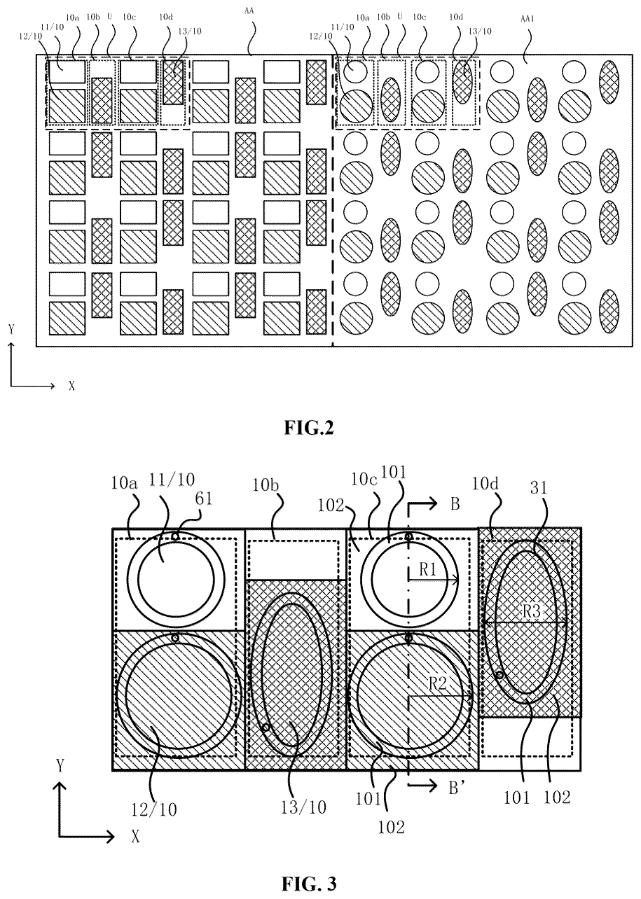

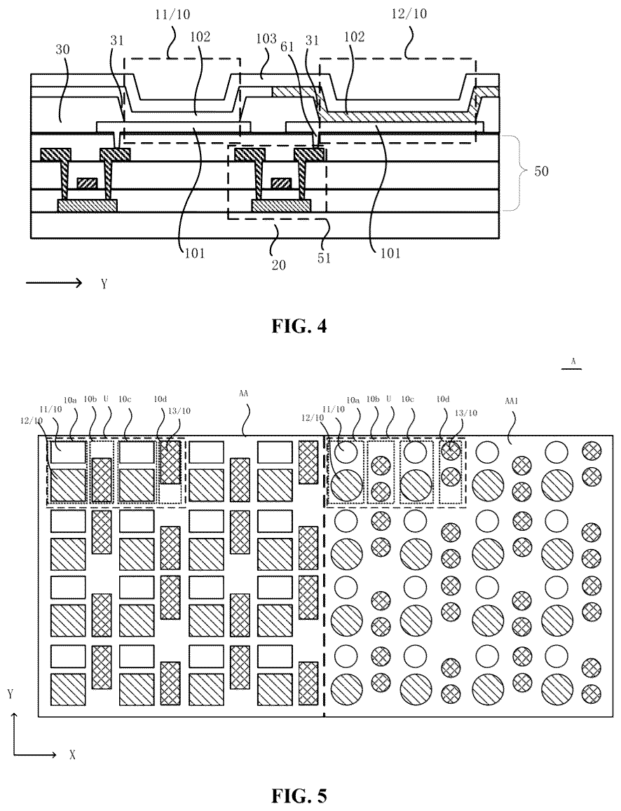

The present disclosure provides a display panel and a display device. FIG. 1 illustrates a top view of an exemplary display panel provided by one embodiment of the present disclosure. FIG. 2 illustrates an A-A′-sectional view of the display panel in FIG. 1. FIG. 3 illustrates a type of repeating units in the display area of the display panel according to various disclosed embodiments of the present disclosure. FIG. 4 shows a B-B′-sectional view of FIG. 3.

As shown in FIGS. 1-4, the present disclosure provides a display panel. The display panel may include a display area AA. The display area AA may include a first display area AA1.

The display area AA may include a plurality of repeating units U. The repeating units U may include a plurality of light-emitting elements 10. The light-emitting elements 10 may include a first color light-emitting element 11, a second color light-emitting element 12 and a third color light-emitting element 13.

The repeating unit U may include a first light-emitting element column 10a, a second light-emitting element column 10b, a third light-emitting element column 10c and a fourth light-emitting element column 10d sequentially arranged in a first direction X.

The first light-emitting element column 10a and the third light-emitting element column 10c each may include a first color light-emitting element 11 and a second color light-emitting element 12 arranged in the second direction Y, and the arrangement manner of the light-emitting elements 10 in the first light-emitting element column 10a may be same as the arrangement manner of the light-emitting elements 10 in the third light-emitting element column 10c. The first direction X may intersect with the second direction Y.

The second light-emitting element column 10b and the fourth light-emitting element column 10d each may include a third color light-emitting element 13, and the third color light-emitting elements 13 in the second light-emitting element column 10b and the third color light-emitting elements 10d in the fourth light-emitting element column 10d 13 may be arranged in a staggered manner in the first direction X.

In the direction perpendicular to the plane of the display panel, the light-emitting element 10 may include an anode 101, a light-emitting material layer 102 and a cathode 103 that are stacked in sequence.

In the first display area AA1, in the direction perpendicular to the plane of the display panel, in the third color light-emitting element 13, the shape of the anode 101 may include an arc-shaped edge.

Specifically, the display panel may include a display area AA, and the display area AA may be used to display a picture. The display panel may also include a non-display area NA surrounding the display area AA. The non-display area NA may not display image and may be configured to dispose gate driving circuits, and driving chips, etc. The display area AA may include a first display area AA1. The first display area AA1 may be used as a reserved area for optical components. For example, the area corresponding to the first display area AA1 may be configured to place photosensitive components. The photosensitive components may be camera modules and light sensors, distance sensors, depth sensors, iris recognition sensors, or infrared sensors, etc., but are not limited to these.

It should be noted that the first display area AA1 may be a rectangular area, a circular area, or an elliptical area, etc., and the position of the first display area AA1 may be set on either side of the display panel. Those skilled in the art may adjust the shape and the position of the first display area AA1 according to actual needs, and the embodiment of the present disclosure does not specifically limit this.

The display area AA may include a plurality of repeating units U. The minimum repeating unit U mentioned here may refer to the light-emitting elements 10 containing all colors, and may be the smallest unit repeatability arranged in the direction X or the second direction Y among all the light-emitting elements 10 arranged in the first display area AA1. The repeating unit U may include a first light-emitting element column 10a, a second light-emitting element column 10b, a third light-emitting element column 10c and a fourth light-emitting element column 10d sequentially arranged in the first direction X. The first light-emitting element column 10a and the third light-emitting element column 10c each may include a first color light-emitting element 11 and a second color light-emitting element 12 arranged in the second direction Y, and the arrangement manner of the light-emitting elements 10 in the first light-emitting element column 10a may be same as the arrangement manner of the light-emitting elements 10 in the third light-emitting element column 10c. Both the second light-emitting element column 10b and the fourth light-emitting element column 10d may include a third color light-emitting element 13, and the third color light-emitting elements 13 in the second light-emitting element column 10b and the third color light-emitting elements 13 in the fourth light-emitting element column 10d may be staggered and arranged in the first direction X. The first direction X and the second direction Y may intersect with each other. In one embodiment, the first direction X may be perpendicular to the second direction Y.

The third color light-emitting elements 13 in the second light-emitting element column 10b in the minimum repeating unit U and the third color light-emitting elements 13 in the fourth light-emitting element column 10d may be arranged in a staggered manner in the first direction X, which may be beneficial to reducing the degree of diffraction of the external light when bypassing the first the light-emitting element 10 in the minimum repeating unit U in the display area AA1 and thereby may reduce the impact of the diffraction phenomenon on the optical performance of the optical element.

In the direction perpendicular to the plane of the display panel, the light-emitting element 10 may include an anode 101, a light-emitting material layer 102 and a cathode 103 that are stacked in sequence. In one embodiment, the anode 101 may include at least two conductive layers. For example, the anode 101 may include at least a first conductive layer and a second conductive layer. The material of the first conductive layer may include indium tin oxide (ITO), and the material of the second conductive layer may include metal material, such as silver, etc. In the first display area AA1, external light may need to bypass the anode 101 of the light-emitting element 10 and be directed to the optical element provided in the first display area AA1.

In the first display area AA1, in the direction perpendicular to the plane of the display panel, in the third color light-emitting element 13, the shape of the anode 101 may include an arcs-shaped edge, which may be conducive to reducing the degree of diffraction of the external light when bypassing the anode 101 of the third color light-emitting element 13 in the first display area AA1, thereby reducing the impact of the diffraction phenomenon on the optical performance of the optical element.

Further, referring to FIGS. 1-4, in some embodiments, in the first display area AA1, in the direction perpendicular to the plane of the display panel, in the third color light-emitting element 13, the shape of the anode 101 may be an ellipse, and the major axis of the ellipse may extend in the second direction Y.

Specifically, in the first display area AA1, in the direction perpendicular to the plane of the display panel, in the third color light-emitting element 13, the shape of the anode 101 may be an ellipse, which may be conducive to reducing the degree of diffraction of the external light when bypassing the anode 101 of the third color light-emitting element in the first display area AA1, thereby reducing the impact of the diffraction phenomenon on the optical performance of the optical element.

At the same time, in the repeating unit U, the first light-emitting element column 10a, the second light-emitting element column 10b, the third light-emitting element column 10c and the fourth light-emitting element column 10d may be arranged in the first direction X. The first light-emitting element column 10a and the third light-emitting element columns 10c each may include a first color light-emitting element 11 and a second-color light-emitting element 12 arranged in the second direction Y. For example, the lengths of the first light-emitting element column 10a and the second light-emitting element column 10b in the repeating unit U in the second direction Y may be relatively long. The second light-emitting element column 10b and the fourth light-emitting element column 10d each may include a third color light-emitting element 13. Accordingly, in the first display area AA1, in the direction perpendicular to the plane of the display panel, in the third color light-emitting element 13, the shape of the anode 101 may an ellipse with its major axis extending in the second direction Y. Thus, while the arrangement of the first color light-emitting elements 11 and the second color light-emitting elements 12 in the first light-emitting element column 10a and the second light-emitting element column 10b may not be affected, it may be beneficial to increase the installation area of the third color light-emitting element 13 in the first display area AA1, thereby avoiding the phenomenon of color shift caused by the small area of the third color light-emitting element 13 in the first display area AA1, which may be beneficial to improving the display effect of the first display area AA1.

Further, referring to FIGS. 1-4, in some embodiments, the ratio of the major axis of the ellipse to the minor axis of the ellipse may be K, and 2≤K≤3.

Specifically, in the first display area AA1, in the direction perpendicular to the plane of the display panel, in the third color light-emitting element 13, the shape of the anode 101 may be an ellipse, the major axis of the ellipse may extend in the second direction Y, and the minor axis of the ellipse may extend in the first direction X. The ratio between the major axis of the ellipse to the minor axis of the ellipse may be K, and 2≤K≤3. When the ratio between the major axis of the ellipse and the minor axis of the ellipse is less than approximately 2, the installation area of the third color light-emitting element 13 in the first display area AA1 may be smaller, which may easily cause the color shift during display in the first display area AA1.

When the ratio of the major axis of the ellipse to the short axis of the ellipse is greater than approximately 3, the length of the anode 101 of the third color light-emitting element 13 in the first display area AA1 may be longer in the second direction Y, affecting the arrangement of the first color light-emitting elements 11 and the second color light-emitting elements 12 in the first light-emitting element column 10a and the third light-emitting element column 10c in the repeating unit U.

In the first display area AA1, in the direction perpendicular to the plane of the display panel, in the third color light-emitting element 13, the shape of the anode 101 may be an ellipse, the major axis of the ellipse may extend in the second direction Y, and the minor axis of the ellipse may extend in the second direction Y. The ratio between the major axis of the ellipse and the minor axis of the ellipse may be K, and 2≤K≤3, while increasing the disposing area of the third color light-emitting elements in the display area AA1, the arrangement of the first color light-emitting element 11 and the second color light-emitting element 12 in the first light-emitting element column 10a and the third light-emitting element column 10c in the same repeating unit U may not be affected.

It should be noted that this embodiment exemplarily shows 2≤K≤3. In other embodiments of the present disclosure, the ratio of the major axis of the ellipse to the minor axis of the ellipse may also be set to other values according to design requirements, and will not be described in detail here.

Further, referring to FIGS. 1-4, in some embodiments, the first color light-emitting element 11 may be a red light-emitting element, the second color light-emitting element 12 may be a green light-emitting element, and the third color light-emitting element 13 may be a blue light-emitting element.

In the first display area AA1, in the direction perpendicular to the plane of the display panel, the shapes of the anode 101 in the first color light-emitting element 11 and the anode 101 in the second color light-emitting element 12 may be both circular. The radius of the anode 101 may be R1, the radius of the anode 101 of the second color light-emitting element 12 may be R2, the minor axis of the ellipse is R3, and R1:R2:R3=1:(1.2-1.4):(1.1-1.3).

Specifically, in the first display area AA1, in the direction perpendicular to the plane of the display panel, the shapes of the anode 101 in the first color light-emitting element 11 and the anode 101 in the second color light-emitting element 12 may be both circular. The shape of the anode 101 in the third light-emitting element 13 may be an ellipse. The shape of the anode 101 in the third-color light-emitting element 13 may be different from the shapes of the anode 101 in the first-color light-emitting element 11 and the shape of the anode 101 in the second-color light-emitting element 12, which may be beneficial to reducing the degree of diffraction of the external light when bypassing the anode 101 of the first color light-emitting element 11, the anode 101 of the second color light-emitting element 12, and the anode 101 of the third color light-emitting element 13 in the first display area AA1, i.e., may be beneficial to mitigating the diffraction phenomenon of the external light when bypassing through the first display area AA1, thereby reducing the impact of the diffraction phenomenon on the optical performance of the optical element.

At the same time, compared with the shape of the anode 101 in the light-emitting element 10 in the display area AA except the first display area AA1, which may be rectangular, in the first display area AA1, in the direction perpendicular to the plane of the display panel, the shapes of the anode 101 in the first color light-emitting element 11 and the anode 101 in the second color light-emitting element 12 may be both circular. The shape of the anode 101 in the third color light-emitting element 13 may be elliptical, which may be beneficial to increasing the light transmittance of the first display area AA1. Accordingly, it may be beneficial to improve the optical performance of the optical elements arranged in the corresponding area of the first display area AA1.

The first color light-emitting element 11 may be a red light-emitting element, the second color light-emitting element 12 may be a green light-emitting element, and the third color light-emitting element 13 may be a blue light-emitting element. In the first display area AA1, the radius of the anode 101 of the first color light-emitting element 11 may be R1, the radius of the anode 101 in the second color light-emitting element 12 may be R2, and the length of the short axis of the ellipse may be R3; and R1:R2:R3=1:(1.2-1.4):(1.1-1.3). Accordingly, the light-emitting effects of the first color light-emitting element 11, the second color light-emitting element 12 and the third color light-emitting element 13 in the first display area AA1 may tend to be the same, which may effectively alleviate the color shift phenomenon in the first display area AA1 and improve the display effect of the first display area AA1.

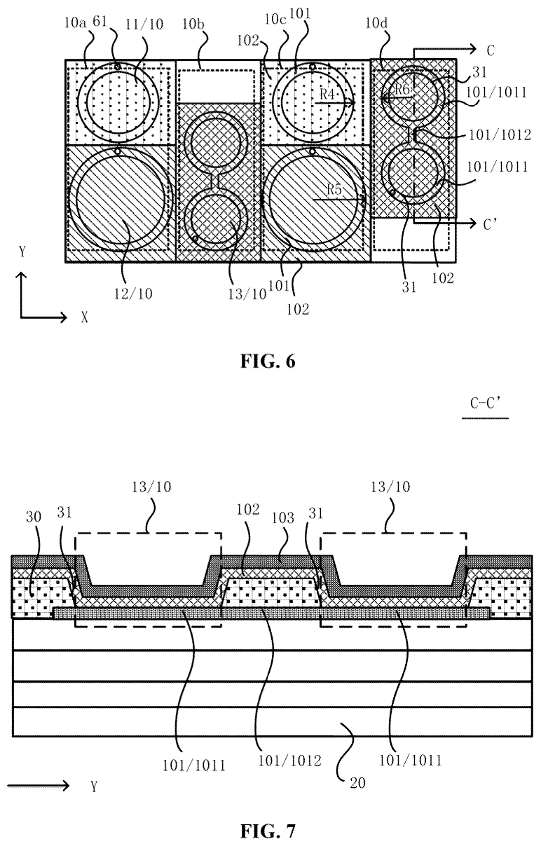

FIG. 5 is another enlarged schematic view of the section A of the display panel shown in FIG. 1. FIG. 6 is a schematic top view of another exemplary repeating unit in the first display area of the display panel provided by the present disclosure. FIG. 7 is a C-C′ sectional view of the display panel in FIG. 6. Referring to FIG. 1 and as shown in FIGS. 5-7, in some embodiments, in the first display area AA1 and in the third color light-emitting element 13, the anode 101 may include at least two main members 1011 arranged in the second direction Y, and a connection member 1012 connecting two adjacent main members 1011.

Specifically, in the repeating unit U, the first light-emitting element column 10a, the second light-emitting element column 10b, the third light-emitting element column 10c and the fourth light-emitting element column 10d may be arranged in the first direction X, and the first light-emitting element column 10a and the third light-emitting element column 10c may both include a first color light-emitting element 11 and a second color light-emitting element 12 arranged in the second direction Y. For example, the length of the first light-emitting element column 10a and the second light-emitting element column 10b in the repeating unit U in the second direction Y may be longer. The second light-emitting element column 10b and the fourth light-emitting element column 10d each may include a third color light-emitting element 13.

Accordingly, in the first display area AA1, the anode 101 of the third color light-emitting element 13 may include at least two main members 1011 arranged in the second direction Y, while not affecting the arrangement of the first light-emitting elements 11 and the second light-emitting elements 12 in the first light-emitting element column 10a and the third light-emitting element column 10c, it may be conducive to increasing the arrangement area of the third color light-emitting elements 11 in the first display area AA1. Accordingly, the phenomenon of color shift caused by the small area of the third color light-emitting element 13 in the first display area AA1 may be avoided, which may be beneficial to improving the display effect of the first display area AA1.

In the first display area AA1, two adjacent main members 1011 of the anode 101 of the third color light-emitting element 13 may be connected through the connection member 1012, thereby realizing signal transmission between the main members 1011 of the same third color light-emitting element 13. At the same time, in the first display area AA1, two adjacent main members 1011 of the anode 101 in the third color light-emitting element 13 may be provided with the connection member 1012, which may be beneficial to reducing the degree of diffraction of external light when bypassing the anode 101 of the third color light-emitting element 13 in the first display area AA1, thereby reducing the impact of the diffraction phenomenon on the optical performance of the optical element.

It should be noted that FIG. 6 exemplarily shows that in the first display area AA1, the anode 101 of the third color light-emitting element 13 may include two main members 1011. In other embodiments of the present disclosure, in the first display area AA1, the number of the main members 1011 in the anode 101 of the third color light-emitting element 13 may also be three or more, and the present disclosure will not repeat one by one here.

Further, referring to FIG. 1 and FIGS. 5-7, in some embodiments, in the first display area AA1 and in the direction perpendicular to the plane of the display panel, the shape of the main member 1011 of the third color light-emitting element 13 may be a circle.

Specifically, compared with the shape of the anode 101 in the light-emitting element 10 in the display area AA except the first display area AA1, which may be rectangular, in the first display area AA1 and in the direction perpendicular to the plane of the display panel, in the third color light-emitting element 13, the shape of the main member 1011 may be circular, which may be beneficial to increasing the light transmittance of the first display area AA1 and improving the optical performance of the optical elements arranged in the corresponding area of the first display area AA1.

It should be noted that FIG. 6 exemplarily shows that, in the first display area AA1 and in the direction perpendicular to the plane where the display panel is located, in the third color light-emitting element 13, the shape of the main body 1011 may be circular. In other embodiments of the present disclosure, in the direction perpendicular to the plane of the display panel, the shape of the main member 1011 in the third color light-emitting element 13 may also be a polygon with a number of sides greater than or equal to 7, which may also be conducive to increasing the light transmittance of the first display of the area AA1 and may be beneficial to improving the optical performance of the optical elements arranged in the corresponding area of the first display area AA1. In other embodiments of the present disclosure, in the first display area AA1, in the direction perpendicular to the plane of the display panel, the shape of the main member 1011 of the third color light-emitting element 13 may also be other quasi-circular shapes, and the disclosure will not be described in detail here.

Further, referring to FIG. 1 and FIGS. 5-7, in some embodiments, in the first display area AA1 and in the direction perpendicular to the plane of the display panel, the anode 101 of the first color light-emitting element 11, the anode 101 of the second light-emitting element 12 and the main member 1011 in the third color light-emitting element 13 may all be circular.

Specifically, compared with the shape of the anode 101 in the light-emitting element 10 in the display area AA except the first display area AA1, which may be rectangular, in the first display area AA1 and in the direction perpendicular to the plane of the display panel, the shapes of the anode 101 of the first color light-emitting element 11, the anode 101 of the second color light-emitting element 12 and the main member 1011 of the third color light-emitting element 13 may all be circular, which may be beneficial to increasing the light transmittance of the first display area AA1 and improving the optical performance of the optical elements disposed in the corresponding area of the first display area AA1.

At the same time, in the first display area AA1 and in the direction perpendicular to the plane of the display panel, the shapes of the anode 101 of the first color light-emitting element 11, the anode 101 of the second color light-emitting element 12 and the main member 1011 of the third color light-emitting element 13 may be all circular. Further, in the first display area AA1, two adjacent main members 1011 of the anode 101 of the third color light-emitting element 13 may be provided with a connection member 1012. The shape of the anode 101 of the third color light-emitting element 13 may be different from the shapes of the anode 101 of the first color light-emitting element 11 and the anode 101 of the second color light-emitting element 12, which may be helpful to reduce the diffraction degree of the external light when bypassing the anode 101 of the first color light-emitting element 11, the anode of the second color light-emitting element 12 in the first display area AA1 and the anode 101 of the third color light-emitting element 13, for example, it may be helpful to alleviate the diffraction phenomenon of external light after passing through the first display area AA1, thereby reducing the impact of diffraction phenomenon on the optical performance of the optical element.

Further, referring to FIG. 1 and FIGS. 5-7, in some embodiments, the first color light-emitting element 11 may be a red light-emitting element, the second color light-emitting element 12 may be a green light-emitting element, and the third color light-emitting element 13 may be a blue light-emitting element. In the first display area AA1, the radius of the anode 101 of the first color light-emitting element 11 may be R4, the radius of the anode 101 of the second color light-emitting element 12 may be R5, and the radius of the main member 1011 of the third color light-emitting element 13 may be R6. In one embodiment, R4:R5:R6=1:(1.2-1.3):(1.1-1.2).

Specifically, the first color light-emitting element 11 may be a red light-emitting element, the second color light-emitting element 12 may be a green light-emitting element, and the third color light-emitting element 13 may be a blue light-emitting element. In the first display area AA1, the radius of the anode 101 of the first color light-emitting element 11 may be R4, the radius of the anode 101 of the second color light-emitting element 12 may be R5, the radius of the main member 1011 of the third color light-emitting element 13 may be R6, and R4:R5:R6=1:(1.2-1.3):(1.1-1.2). Such a configuration may make the light emission effects of the first color light-emitting element 11, the second color light-emitting element 12 and the third color light-emitting element 13 in the first display area AA1 tend to be the same, effectively alleviating the color shift phenomenon in the first display area AA1 and improving the display effect of the first display area AA1.

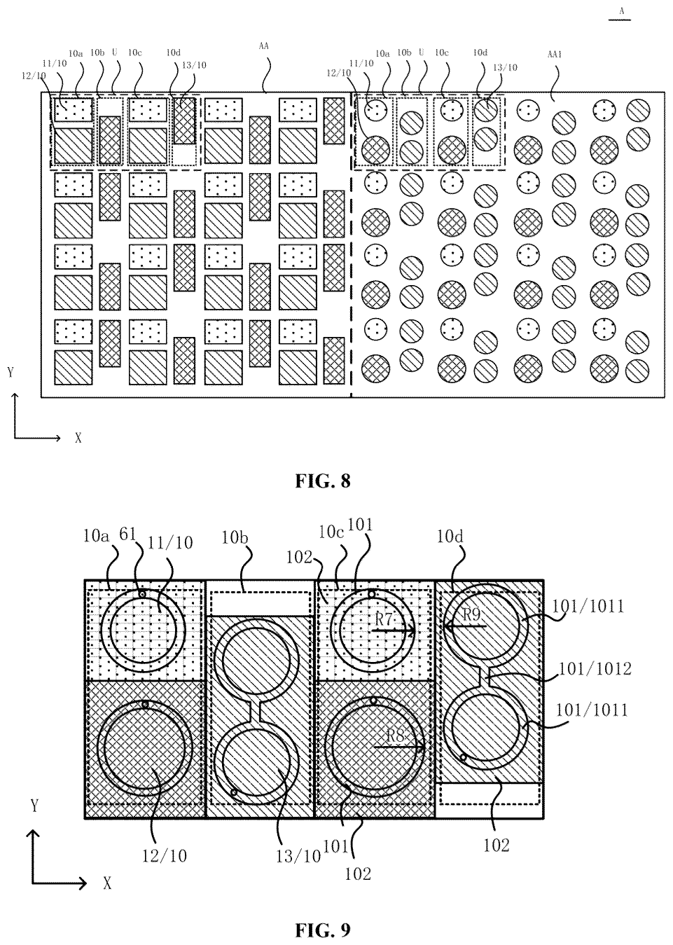

FIG. 8 is another enlarged schematic view of the section A of the display panel shown in FIG. 1. FIG. 9 is a schematic top view of another repeating unit in the first display area of the display panel provided by the present disclosure. As shown in FIGS. 8-9 and referring to FIG. 1, in some embodiments, in the first display area AA1, the first color light-emitting element 11 may be a red light-emitting element, the second color light-emitting element 12 may be a blue light-emitting element, and the third color light-emitting element 13 may be a green light-emitting element. In the first display area AA1, the radius of the anode 101 of the first color light-emitting element 11 may be R7, the radius of the anode 101 of the second color light-emitting element 12 may be R8, and the radius of the main member 1011 in the third color light-emitting element 13 may be R9. In one embodiment, R7:R9:R8=1:(1.2-1.3):(1.1-1.2).

Specifically, in the first display area AA1, when the first color light-emitting element 11 is a red light-emitting element, the second color light-emitting element 12 is a blue light-emitting element, and the third color light-emitting element 13 is a green light-emitting element. The radius of the anode 101 of the first color light-emitting element 11 may be R7, the radius of the anode 101 of the second color light-emitting element 12 may be R8, and the radius of the main member 1011 in the third color light-emitting element 13 may be R9, and R7:R9:R8=1:(1.2-1.3):(1.1-1.2). Accordingly, the light emission effects of the first color light-emitting element 11, the second color light-emitting element 12 and the third color light-emitting element 13 in the first display area AA1 may tend to be the same, which may effectively ease the color shift phenomenon in the first display area AA1, and the display effect of the first display area AA1 may be improved.

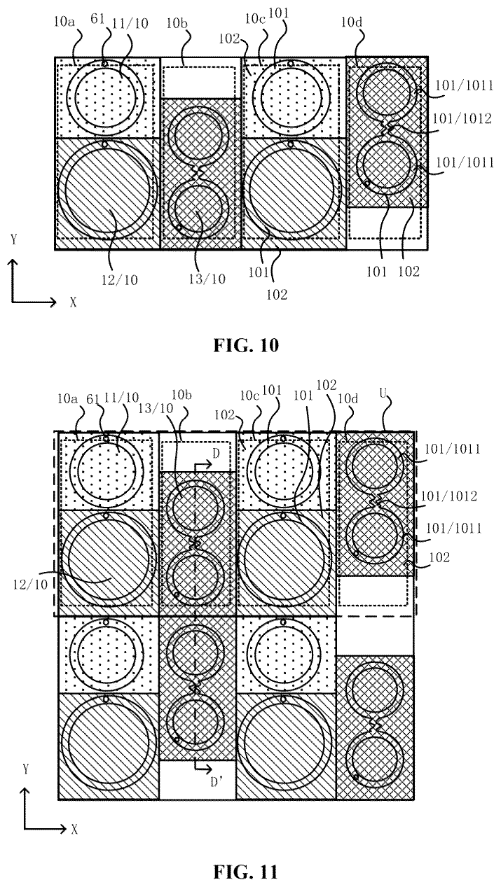

FIG. 10 is a schematic top view of another repeating unit group in the first display area of an exemplary display panel provided by the present disclosure. As shown in FIG. 10 and referring to FIG. 1 and FIG. 5, in some embodiments, the connection member 1012 may include at least one bending structure.

Specifically, in the first display area AA1, two adjacent main members 1011 of the anode 101 of the third color light-emitting element 13 may be provided with a connection member 1012. The connection member 1012 may include at least one bending structure, which may be conducive to further reducing the diffraction degree of the external light when bypassing the anode 101 of the third color light-emitting element 13 in a display area AA1. Thus, the impact of the diffraction phenomenon on the optical performance of the optical elements may be reduced.

It should be noted that FIG. 10 exemplarily shows that the connection member 1012 may include three bending structures. In other embodiments of the present disclosure, the connection member 1012 may also include other numbers of bending structures, which is not limited in the present disclosure.

FIG. 11 is a schematic top view of a repeating unit group in the first display area of the display panel provided by the present disclosure. As shown in FIG. 11, and referring to FIGS. 1-5, in some embodiments, in the first display area AA1 and in the first direction X, among the two adjacent third color light-emitting elements 13, the bending directions of the corresponding bending structures in the two adjacent connection members 1012 may be opposite.

Specifically, in the first display area AA1, two adjacent main members 1011 of the anode 101 of the third color light-emitting element 13 may be provided with the connection member 1012. In the first direction X, two adjacent third color light-emitting elements 13 may be provided with the connection member 1012. The bending directions of the corresponding bending structures in the two adjacent connection members 1012 may be opposite, which may be conducive to further reducing the degree of diffraction of external light when bypassing the anode 101 of the third color light-emitting element 13 in the first display area AA1, thereby reducing the effect of diffraction phenomenon on the optical performance of optical components.

Similarly, in the second direction Y, the bending directions of the corresponding bending structures in the two adjacent connection members 1012 of two adjacent third color light-emitting elements 13 may also be set in opposite directions, which may be beneficial to further reducing the diffraction degree of external light when bypassing the anode 101 of the third color light-emitting element 13 in the first display area AA1. Accordingly, the impact of the diffraction phenomenon on the optical performance of the optical element may be reduced.

Further, referring to FIGS. 1-4, in some embodiments, in the first display area AA1, in the direction perpendicular to the plane of the display panel, in the first color light-emitting element 11 and the second color light-emitting element 12, the shapes of the anodes 101 may be circular, which may be beneficial to increasing the light transmittance of the first display area AA1 and improving the optical performance of the optical elements arranged in the corresponding area of the first display area AA1.

It should be noted that FIG. 3 exemplarily shows that, in the first display area AA1 and in the direction perpendicular to the plane of the display panel, in the first color light-emitting element 11 and the second color light-emitting element 12, the shapes of the anodes 101 may be circular. In other embodiments of the present disclosure, in the direction perpendicular to the plane of the display panel, in the first color light-emitting element 11 and the second color light-emitting element 12, the shape of the anode 101 may also be a polygon with the number of sides being greater than or equal to 7, which also be beneficial to increasing the light transmittance of the first display area AA1 and improving the optical performance of the optical elements arranged in the corresponding area of the first display area AA1. In other embodiments of the present disclosure, in the direction perpendicular to the plane of the display panel, the shapes of the anodes 101 in the first color light-emitting element 11 and the second color light-emitting element 12 may also be other round shapes, which may not be limited in the present disclosure.

Further, referring to FIGS. 1-4, in some embodiments, the display panel may further include a substrate 20. The light-emitting elements 10 may be located on one side of the substrate 20. The display panel may also include a pixel definition layer 30. The pixel definition layer 30 may be located on the side of the anode 101 away from the substrate 20. The pixel definition layer 30 may include a plurality of first openings 31. The first opening 31 may expose a portion of the anode 101 corresponding to the first opening 31.

In the first display area AA1, in the direction perpendicular to the plane of the display panel, the shape of the first opening 31 corresponding to the anode 101 of the third color light-emitting element 13 may be an ellipse.

Specifically, the display panel may also include a substrate 20. The substrate 20 may usually be made of a rigid glass substrate, or may also be made of flexible organic materials, such as polyimide or polyethylene terephthalate, etc. The display panel may also include a pixel definition layer 30, which may be located on the side of the anode 101 away from the substrate 20. The pixel definition layer 30 may be used to define the light-emitting area of each light-emitting element 10. The pixel definition layer 30 may include a plurality of first openings 31 corresponding to the anode 101 and exposing at least a portion of the corresponding anode 101. The area of the first opening 31 may be same as the corresponding exposed area of the anode 101.

In the first display area AA1 and in the direction perpendicular to the plane of the display panel, the shape of the anode 101 of the third color light-emitting element 13 may be an ellipse. Correspondingly, the shape of the opening 31 corresponding to the anode 101 of the third color light-emitting element 13 may also be an ellipse, and the shape of the anode 101 may match the shape of the corresponding first opening 31, which may be beneficial to increasing the light-emitting area of the third color light-emitting element 13 in the first display area AA1, thereby avoiding the color shift caused by the small light-emitting area of the third color light-emitting element 13 in the first display area AA1, and which may be beneficial to improving the display effect of the first display area AA1.

Further, referring to FIG. 1 and FIGS. 5-7, in some embodiments, the display panel may further include a substrate 20. The light-emitting element 10 may be located on one side of the substrate 20.

The display panel may also include a pixel definition layer 30. The pixel definition layer 30 may be located on the side of the anode 101 away from the substrate 20. The pixel definition layer 30 may include a plurality of first openings 31. The first opening 31 may correspond to the anode 101, and the first opening 31 may expose a portion of the corresponding to the anode 101.

In the first display area AA1, a main member 1011 of the third color light-emitting element 13 may correspond to a first opening 31, and the first opening 31 may expose at least a portion of the corresponding main member 1011. The pixel definition layer 30 may cover the connection member 1012.

Specifically, the display panel may also include a substrate 20. The substrate 20 may usually be made of a rigid glass substrate, or may be made of flexible organic materials, such as polyimide, or polyethylene terephthalate, etc. The display panel may also include a pixel definition layer 30, which may be located on the side of the anode 101 away from the substrate 20. The pixel definition layer 30 may be configured to define the light-emitting area of each light-emitting element 10. The pixel definition layer 30 may include a plurality of first openings 31, and the first openings 31 may be connected to the corresponding to the anode 101. The first opening 31 may expose at least a portion of the corresponding anode 101. The area of the first opening 31 may be the same as the corresponding exposed area of the anode 101.

In the first display area AA1 and the third color light-emitting element 13, the anode 101 may include at least two main members 1011 arranged in the second direction Y, and a connection member 1012 connecting two adjacent main member 1011. One main member 1011 of the third color light-emitting element 13 may correspond to a first opening 31, and the first opening 31 may expose at least a portion of the corresponding main member 1011. For example, in the first display area AA1 and the third color light-emitting element 13, each main member 1011 may be partially exposed through the first opening 31, which may be beneficial to increasing the light-emitting area of the third color light-emitting element 13 in the first display area AA1. Such a configuration may avoid the phenomenon of color shift caused by the small light-emitting area of the third color light-emitting element 13 in the first display area AA1, which may be beneficial to improving the display effect of the first display area AA1. The pixel definition layer 30 may cover the connection member 1012, for example, the first opening 31 may not expose the connection member 1012, and the area corresponding to the third color light-emitting element 13 and the connection member 1012 may not emit light, thereby facilitating the design of the light-emitting area of the third color light-emitting element 13.

Further, referring to FIG. 1 and FIGS. 5-7, in some embodiments, the light-emitting material layer 102 may be located on a side of the pixel definition layer 30 away from the substrate 20. The light-emitting material layer 102 may cover the first opening 31.

In the first display area AA1, in the same third color light-emitting element 13, the light-emitting material layer 102 may cover the main member 1011. In the direction perpendicular to the plane of the display panel, the light-emitting material layer 102 may at least partially overlap with the connection member 1012.

Specifically, the light-emitting material layer 102 may be located on the side of the pixel definition layer 30 away from the substrate 20. The light-emitting material layer 102 may cover the first opening 31, and the first opening 31 may expose at least a portion of the anode 101 corresponding to the first opening 31. Accordingly, the light-emitting material layer 102 may cover the anode 101 exposed by the first opening 31 through the first opening 31.

Because, in the first display area AA1, the first opening 31 may not expose the connection member 1012, in the same third color light-emitting element 13 in the first display area AA1, the light-emitting material layer 102 may cover the main member 1011, and may extend in the vertical direction of the first display area AA1. In the direction of the plane of the display panel, the light-emitting material layer 102 and the connection member 1012 may at least partially overlap. At this time, the pixel definition layer 30 may be spaced between the light-emitting material layer 102 and the connection member 1012. Therefore, the light-emitting material layer 102 in the third color light-emitting element 13 in the first display area AA1 may use a same mask opening with the light-emitting material layer 102 in the third color light-emitting element 13 in the display area AA except the first display area AA1 to perform the evaporation process. Thus, the difficulty of the evaporation process of the light-emitting material layer 102 may be reduced, and the production costs may be reduced.

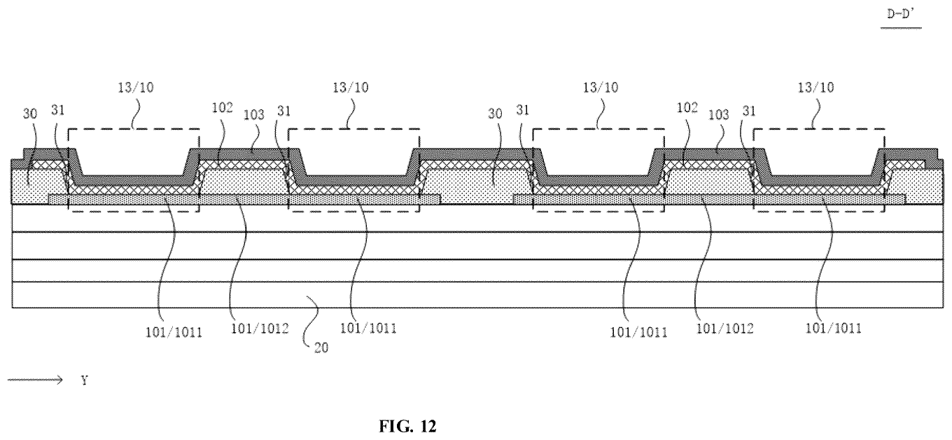

FIG. 12 is a D-D′-sectional view of the display panel shown in FIG. 11. Referring to FIG. 1, FIG. 5, FIG. 11 and FIG. 12, in some embodiments, the display area AA may include at least one repeating unit group U1. The repeating unit group U1 may include two repeating units U arranged in the second direction Y. In the same repeating unit group U1, the light-emitting material layers 102 of the two third color light-emitting elements 13 may be connected.

Specifically, because the third color light-emitting elements 13 in the second light-emitting element column 10b and the third color light-emitting elements 13 in the fourth light-emitting element column 10d in the minimum repeating unit U may be arranged in a staggered manner in the first direction X, in the display area AA, there may be a repeating unit group U1. The repeating unit group U1 may include two repeating units U arranged in the second direction Y. In the same repeating unit group U1, the light-emitting material layers 102 of the two third color light-emitting elements 13 may be connected. For example, in the same repeating unit group U1, the light-emitting material layers 102 in the two third color light-emitting elements 13 may be evaporated using the same mask opening, which may be beneficial to reducing the difficulty of the evaporation process of the light-emitting material layer 102 and reducing production costs.

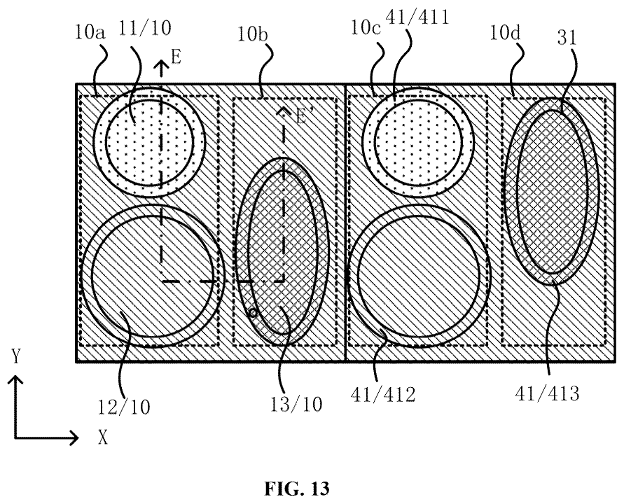

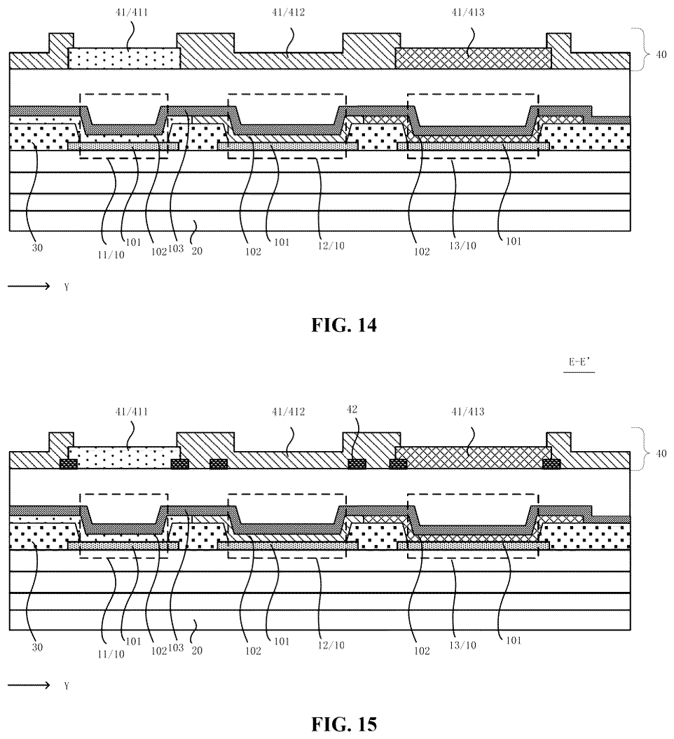

FIG. 13 is a schematic plan view of another exemplary repeating unit in the first display area of the display panel provided by the present disclosure. FIG. 14 is an E-E′-sectional view of the display panel in FIG. 13. Referring to FIGS. 1-2 and as shown in FIGS. 13 and 14, in some embodiments, the display panel may also include a filter layer 40. The filter layer 40 may be located on the side of the light-emitting element 10 away from the base substrate 20. The filter layer 40 may include a plurality of color resistors. 41. The color resistor 41 may correspond to the light-emitting element 10.

In the direction perpendicular to the plane of the display panel, the color resistor 41 and the anode 101 in the corresponding light-emitting element 10 may at least partially overlap. In the first display area AA, in the direction perpendicular to the plane of the display panel, the shape of the color resistor 41 corresponding to the anode 101 of the third color light-emitting element 13 may be an ellipse.

Specifically, the display panel may further include a filter layer 40. The filter layer 40 may be located on the side of the light-emitting element 10 away from the substrate 20. The filter layer 40 may include a plurality of color resistors 41. In one embodiment, the color resistors 41 may include a first-color color resistor 411, a second-color color resistor 412 and a third-color color resistor 413. The color of the first color color resistor 411 may be same as the light-emitting color of the first color light-emitting element 11. The first-color color resistor 411 may be provided correspondingly to the first color light-emitting element 11. The color of the second color color resistor 412 may be same as the light-emitting color of the second color light-emitting element 12, and the third color color resistor 413 may be provided correspondingly to the third color light-emitting element 13. The color resistor 41 may be used to filter the light in the external ambient light that is different from its own color, and may play the role of light filtering. In the direction perpendicular to the plane of the display panel, the color resistor 41 may at least partially overlap with the anode 101 of the corresponding light-emitting element 10 such that the light emitted by the light-emitting element 10 may be emitted from the surface of the display panel after passing through the corresponding color resistor 41; and the setting of the color resistor 41 may not affect the display of the display panel.

In the first display area AA, in the direction perpendicular to the plane of the display panel, the shape of the anode 101 in the third color light-emitting element 13 may be an ellipse, and the shape of the first opening 31 corresponding to the anode 101 in the third color light-emitting element 13 may also be an ellipse. Correspondingly, the shape of the color resistor 41 corresponding to the anode 101 in the third color light-emitting element 13 may be an ellipse, thereby achieving the normal light emission of the third color light-emitting element 13.

In one embodiment, in the filter layer 40, the shape of the first-color color resistor 411 may be same as the shape of the anode 101 in the corresponding first color light-emitting element 11, and the shape of the third-color color resistor 413 may be same as the shape of the anode 101 of the corresponding third-color color resistor 411. In the direction perpendicular to the plane of the display panel, the second-color color resistor 412 may at least partially overlap with the first-color color resistor 411 and the third-color color resistor 413, and the second-color color resistor 412 may not overlap with the first opening 31 corresponding to the first-color color resistor 411, and the second-color color resistor 412 may not overlap with the first opening 31 corresponding to the third-color color resistor 413. Such a configuration may effectively improve the color mixing phenomenon of the display panel.

When forming the filter layer 40, the first-color color resistor 411 and the third-color color resistor 413 may be formed first, and then the second-color color resistor 412 may be formed.

In one embodiment, in the first display area AA, the light shielding member may not be provided in the filter layer 40, and the second-color color resistor 412 may be provided in the area of the filter layer 40 corresponding to the pixel definition layer 30, which may be beneficial to reducing the phenomenon of edge visibility and improving the light transmittance of the first display area AA and improving the optical performance of the optical elements disposed in the corresponding area of the first display area AA1.

FIG. 15 is another exemplary E-E′-sectional view of the display panel shown in FIG. 13. Referring to FIGS. 1-2, FIG. 13 and FIG. 15, in one embodiment, the filter layer 40 may also include a light-shielding member 42. In the direction perpendicular to the plane of the display panel, the edge of the anode 101 may at least partially overlap with the light-shielding member 42, which may be beneficial to reducing the visibility of the edge of the anode 101.

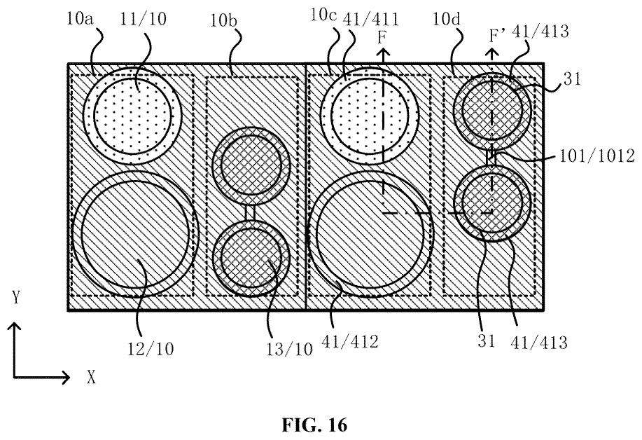

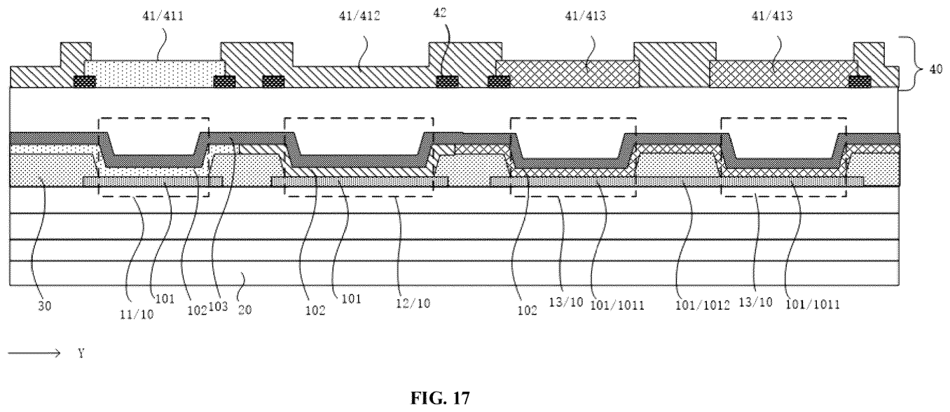

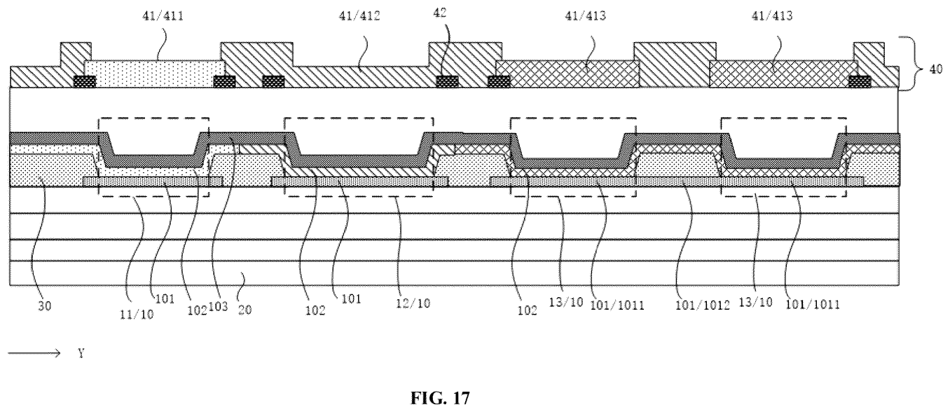

FIG. 16 is a schematic plan view of another exemplary repeating unit in the first display area of the display panel provided by the present disclosure. FIG. 17 is an F-F′-sectional view of the display panel of FIG. 16. Referring to FIG. 1 and FIG. 5 and as shown in FIGS. 16-17, in some embodiments, the display panel may further include a filter layer 40. The filter layer 40 may be located on the side of the light-emitting element 10 away from the substrate 20. The filter layer 40 may include a plurality of color resistors 41. The color resistor 41 may correspond to the light-emitting element 10. In the direction perpendicular to the plane of the display panel, the color resistor 41 and the anode 101 in the corresponding light-emitting element 10 may at least partially overlap.

In the first display area AA1, a main member 1011 of the third color light-emitting element 13 may correspond to a color resistor 41. In the direction perpendicular to the plane of the display panel, the color resistor 41 and the main member 1011 of the corresponding light-emitting element 10 may at least partially overlap, and the color resistor 41 and the connection member 1012 may not overlap.

Specifically, the display panel may further include a filter layer 40. The filter layer 40 may be located on the side of the light-emitting element 10 away from the substrate 20. The filter layer 40 may include a plurality of color resistors 41. In one embodiment, the color resistor 41 may include a first-color color resistor 411, a second-color color resistor 412 and a third-color color resistor 413. The color of the first-color color resistor 411 may be same as the light-emitting color of the first color light-emitting element 11. The first-color color resistor 411 may be provided correspondingly to the first color light-emitting element 11. The second-color color resistor 412 may have a same color as the second color light-emitting element 12, and the third-color color resistor 413 may be provided correspondingly to the third color light-emitting element 13. The color resistor 41 may be used to filter the light in the external ambient light that is different from its own color, and may play the role of light filtering. In the direction perpendicular to the plane of the display panel, the color resistor 41 may at least partially overlap with the anode 101 of the corresponding light-emitting element 10 such that the light emitted by the light-emitting element 10 may be emitted from the surface of the display panel after passing through the corresponding color resistor 41; and the setting of the color resistor 41 may not affect the display of the display panel.

In the first display area AA, one main member 1011 of the third color light-emitting element 13 may correspond to one color resistor 41. In the direction perpendicular to the plane of the display panel, the color resistor 41 and the main member 1011 of the corresponding light-emitting element 10 may at least partially overlap. For example, one main member 1011 of the third color light-emitting element 13 may correspond to a third-color color resistor 413, and the third-color color resistor 413 and the corresponding main member 1011 of the light-emitting element 10 may at least partially overlap, thereby achieving the normal light emission of the third color light-emitting element 13. The area corresponding to the connection member 1012 of the third color light-emitting element 13 may not be used for emitting light. Correspondingly, the area corresponding to the connection member 1012 of the third-color color resistor 413 may not need to be provided with the third-color color resistor 413.

Further, referring to FIGS. 1-4, in some embodiments, the display panel may further include an array layer 50. The array layer 50 may be located between the substrate 20 and the light-emitting element 10. The array layer 50 may include a plurality of pixel circuits 51, and an anode 101 may be electrically connected to the pixel circuit 51 through the first via hole 61. In the light-emitting elements 10 arranged in the second direction Y, the first via holes 61 may be linearly arranged in the second direction Y.

Specifically, the display panel may also include an array layer 50. The array layer 50 may be located between the substrate 20 and the light-emitting element 10. The array layer 50 may include a plurality of pixel circuits 51. The pixel circuit 51 may be connected to the light-emitting element 10 through the first via hole 61, thereby enabling the pixel circuit 51 to drive the light-emitting element 10 electrically connected thereto to emit light.

It can be understood that the specific implementation of the pixel circuit 51 may be set by those skilled in the art according to the actual situation, and is not limited here. For example, the pixel circuit 51 may include “7TIC”, or “2TIC”, etc. “T” refers to a transistor, and “C” refers to a capacitor.

The display panel may also include a signal line (not shown in the figure), and the signal line may be electrically connected to the light-emitting element 10 through the pixel circuit 51. In the light-emitting elements 10 arranged in the second direction Y, the first via holes 61 may be arranged as a straight line in the second direction Y, thereby facilitating the realization of the electrical connection with the light-emitting elements arranged in the second direction Y through the signal lines extending in the second direction Y, which may help to reduce the difficulty of arranging signal lines.

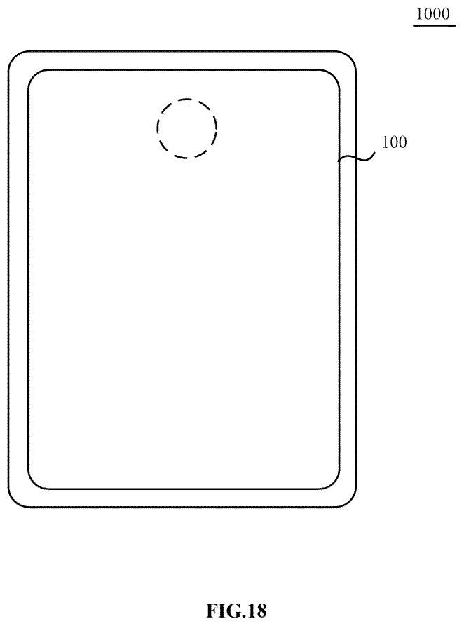

The present disclosure also provides a display device. FIG. 18 illustrates an exemplary display device according to various disclosed embodiments of the present disclosure. As shown in FIG. 18, the display device 1000 provided in one embodiment of the present disclosure may include a display panel 100 provided by the above embodiment of the present disclosure. It can be understood that the display device 1000 provided by the embodiment of the present disclosure may be a computer, a television, a vehicle-mounted display device, or other display device with a display function, and the present disclosure does not impose specific limitations on this. The display device 1000 provided by the embodiment of the present disclosure may include the beneficial effects of the display panel 100 provided by the embodiment of the present disclosure. For details, reference may be made to the specific description of the display panel 100 in the above embodiments, which will not be described again in this embodiment.

It can be seen from the above embodiments that the display panel and display device provided by the present disclosure may at least achieve the following beneficial effects.

In the display panel provided by the present disclosure, the display area may include a plurality of repeating units. In a smallest repeating unit, the third color light-emitting element in the second light-emitting element column and the third color light-emitting element in the fourth light-emitting element column may be staggered in the first direction, which may be conducive to reducing the degree of diffraction of external light when bypassing the light-emitting element in the smallest repeating unit in the first display area, thereby reducing the impact of diffraction phenomena on the optical performance of the optical element. At the same time, in the first display area, in the direction perpendicular to the plane of the display panel, in the third color light-emitting element, the shape of the anode may include an arc edge, which may be conducive to reducing the degree of diffraction of the external light when bypassing the anode of the third color light-emitting element in the first display area, thereby reducing the impact of diffraction phenomena on the optical performance of the optical element.

Although some specific embodiments of the disclosure have been described in detail by way of examples, those skilled in the art will understand that the above examples are for illustration only and are not intended to limit the scope of the disclosure. Those skilled in the art will understand that the above embodiments may be modified without departing from the scope and spirit of the disclosure. The scope of the disclosure is defined by the appended claims.

What is claimed is:

1. A display panel, comprising:
a display area, including a first display area and a plurality of repeating units,
wherein:
a repeating unit of the plurality of repeating units includes a plurality of light-emitting elements;
the plurality of light-emitting elements include a first color light-emitting element, a second color light-emitting element and a third color light-emitting element;
the plurality of repeating units include a first light-emitting element column, a second light-emitting element column, a third light-emitting element column and a fourth light-emitting element column sequentially arranged in a first direction;
the first light-emitting element column and the third light-emitting element column each includes a first color light-emitting element and a second color light-emitting element arranged in a second direction, and an arrangement manner of light-emitting elements in the first light-emitting element column is same as an arrangement manner of light-emitting elements in the third light-emitting element column, and the first direction intersects with the second direction;
the second light-emitting element column and the fourth light-emitting element column each includes a third color light-emitting element, and third color light-emitting elements in the second light-emitting column and third color light-emitting elements in the fourth light-emitting element column are arranged in a staggered manner in the first direction;
in a direction perpendicular to a plane of the display panel, a light-emitting element includes an anode, a light-emitting material layer and a cathode that are stacked in sequence; and
in the first display area, in the direction perpendicular to the plane of the display panel, in the third color light-emitting element, a shape of the anode includes an arc-shaped edge.

2. The display panel according to claim 1, wherein:
in the first display area, in the direction perpendicular to the plane of the display panel, in the third color light-emitting element, a shape of the anode is an ellipse, and a major axis of the ellipse extends in the second direction.

3. The display panel according to claim 2, wherein:
a ratio of the major axis of the ellipse to a minor axis of the ellipse is K, and 2≤K≤3.

4. The display panel according to claim 2, wherein:
the first color light-emitting element is a red light-emitting element, the second color light-emitting element is a green light-emitting element, and the third color light-emitting element is a blue light-emitting element; and
in the first display area, in the direction perpendicular to the plane of the display panel, the anode in the first color light-emitting element and the anode in the second color light-emitting element are both circular, a radius of the anode in the first color light-emitting element is R1, a radius of the anode in the second color light-emitting element is R2, the minor axis of the ellipse is R3, and R1:R2:R3=1:(1.2-1.4):(1.1-1.3).

5. The display panel according to claim 1, wherein:
in the first display area and in the third color light-emitting element, the anode includes at least two main members arranged in the second direction and a connection member connecting two adjacent main members.

6. The display panel according to claim 5, wherein:
in the first display area and in the direction perpendicular to the plane of the display panel, in the third color light-emitting element, a shape of the main member is one of a circle and a polygon with a number of sides greater than or equal to 7.

7. The display panel according to claim 6, wherein:
in the first display area and in the direction perpendicular to the plane of the display panel, shapes of the anode in the first color light-emitting element, the anode in the second color light-emitting element and the main member in the third color light-emitting element are all circular.

8. The display panel according to claim 7, wherein:
the first color light-emitting element is a red light-emitting element, the second color light-emitting element is a green light-emitting element, and the third color light-emitting element is a blue light-emitting element; and
in the first display area, a radius of the anode in the first color light-emitting element is R4, a radius of the anode in the second color light-emitting element is R5, a radius of the anode in the third color light-emitting element is R5, a radius of the main member is R6, and R4:R5:R6=1:(1.2-1.3):(1.1-1.2).

9. The display panel according to claim 7, wherein:
in the first display area, the first color light-emitting element is a red light-emitting element, the second color light-emitting element is a blue light-emitting element, and the third color light-emitting element is a green light-emitting element; and
in the first display area, a radius of the anode in the first color light-emitting element is R7, a radius of the anode in the second color light-emitting element is R8, a radius of the anode in the third color light-emitting element is R8, a radius of the main member is R9, and R7:R9:R8=1:(1.2-1.3):(1.1-1.2).

10. The display panel according to claim 4, wherein:
the connection member includes at least one bending structure.

11. The display panel according to claim 10, wherein:
in the first display area and in the first direction, among the two adjacent third color light-emitting elements, bending directions of corresponding bending structures in the two adjacent connection members are opposite, and/or, in the second direction, among the two adjacent third color light-emitting elements, bending directions of the corresponding bending structures in the two adjacent connection members are opposite.

12. The display panel according to claim 1, wherein:
in the first display area and in the direction perpendicular to the plane of the display panel, in the first color light-emitting element and the second color light-emitting element, shapes of anodes are all circular, or one of the polygons with a number of sides greater than or equal to 7.

13. The display panel according to claim 2, further comprising:
a substrate, wherein the light-emitting element is located on one side of the substrate;
a pixel definition layer, located on a side of the anode away from the substrate, wherein the pixel definition layer includes a plurality of first openings, a first opening of the plurality of first openings corresponds to an anode, and the first opening exposes at least a portion of the anode corresponding to the first opening; and
in the first display area and in a direction perpendicular to the plane of the display panel, a shape of the first opening corresponding to the anode in the third color light-emitting element is an ellipse.

14. The display panel according to claim 5, further comprising:
a substrate, wherein the light-emitting element is located on one side of the substrate;
a pixel definition layer, located on a side of the anode away from the substrate, wherein the pixel definition layer includes a plurality of first openings, a first opening of the plurality of first openings corresponds to an anode, and the first opening exposes at least a portion of the anode corresponding to the first opening; and
in the first display area, a main member of the third color light-emitting element corresponds to a first opening, the first opening exposes at least a portion of the corresponding main member, and the pixel definition layer cover the connection member.

15. The display panel according to claim 14, wherein:
the light-emitting material layer is located on a side of the pixel definition layer away from the substrate, and covers the first opening; and
in the first display area and a same third color light-emitting element, the light-emitting material layer covers the main member, and in the direction perpendicular to the plane of the display panel, the light-emitting material layer and the connection member at least partially overlap.

16. The display panel according to claim 1, wherein:
the display area includes at least one repeating unit group, and the repeating unit group includes two repeating units arranged in the second direction; and
in the same repeating unit group, the light-emitting material layers in the two third color light-emitting elements are connected.

17. The display panel according to claim 2, further comprising:
a filter layer located on a side of the light-emitting element away from the substrate,
wherein:
the filter layer includes a plurality of color resistors corresponding to the light-emitting elements;
in a direction perpendicular to the plane of the display panel, the color resistor and the anode in the corresponding light-emitting element at least partially overlap; and
in the first display area and in a direction perpendicular to the plane of the display panel, a shape of the color resistor corresponding to the anode in the third color light-emitting element is an ellipse.

18. The display panel according to claim 5, further comprising:
a filter layer located on a side of the light-emitting element away from the substrate,
wherein:
the filter layer includes a plurality of color resistors corresponding to the light-emitting elements;
in a direction perpendicular to the plane of the display panel, the color resistor and the anode in the corresponding light-emitting element at least partially overlap;
in the first display area, a main member of the third color light-emitting element corresponds to one color resistor;
in a direction perpendicular to the plane of the display panel, the color resistor and the main member of the third color light-emitting element color corresponding to the color resistor at least partially overlaps; and
the color resistor does not overlap with the connection member.

19. The display panel according to claim 1, further comprising:
an array layer located between the substrate and the light-emitting element.
wherein:
the array layer includes a plurality of pixel circuits;
the anode is electrically connected to the pixel circuit through a first via hole; and
in the light-emitting elements arranged in the second direction, the first via holes are arranged in a straight line in the second direction.

20. A display device, comprising:
a display panel, including:
a display area, including a first display area and a plurality of repeating units,
wherein:
a repeating unit of the plurality of repeating units includes a plurality of light-emitting elements;
the plurality of light-emitting elements include a first color light-emitting element, a second color light-emitting element and a third color light-emitting element;
the plurality of repeating units include a first light-emitting element column, a second light-emitting element column, a third light-emitting element column and a fourth light-emitting element column sequentially arranged in a first direction;
the first light-emitting element column and the third light-emitting element column each include a first color light-emitting element and a second color light-emitting element arranged in a second direction, and an arrangement manner of the light-emitting elements in the first light-emitting element column is same as an arrangement manner of the light-emitting elements in the third light-emitting element column, and the first direction intersects with the second direction;
the second light-emitting element column and the fourth light-emitting element column each include a third color light-emitting element, and third color light-emitting elements in the second light-emitting column and third color light-emitting elements in the fourth light-emitting element column are arranged in a staggered manner in the first direction;
in a direction perpendicular to a plane of the display panel, a light-emitting element includes an anode, a light-emitting material layer and a cathode that are stacked in sequence; and
in the first display area, in the direction perpendicular to the plane of the display panel, in the third color light-emitting element, a shape of the anode includes an arc-shaped edge.
